(19) United States
(12) Patent Application Publication
(10) Pub. No.: US 2024/0405170 A1
(43) Pub. Date: Dec. 5, 2024

(54) PATTERNING PHOSPHOR LAYERS USING POLYMER MASKS

(71) Applicant: LUMILEDS LLC, San Jose, CA (US)

(72) Inventors: Ronja MISSONG, Aachen (DE); Jens Meyer, Köln (DE); Marinus Johannes Petrus Maria van Gerwen, Bakel (NL)

(73) Assignee: LUMILEDS LLC, San Jose, CA (US)

(21) Appl. No.: 18/680,059

(22) Filed: May 31, 2024

Related U.S. Application Data
(63) Continuation of application No. PCT/US2022/049438, filed on Nov. 9, 2022.
(60) Provisional application No. 63/286,237, filed on Dec. 6, 2021.

(51) Int. Cl. H01L 33/50; H01L 25/075

(52) U.S. Cl. CPC H01L 33/505; H01L 25/0753; H01L 2933/0041

(57) ABSTRACT

A method for depositing patterned phosphor films comprises using a patterned polymer film as a mask to block phosphor deposition, or allow subsequent removal of deposited phosphor, from selected areas of a device surface covered by the polymer film. The method generally comprises disposing the patterned polymer film mask on the device, subsequently depositing the phosphor, and then removing the mask and any phosphor deposited on the mask from the device. The polymer film may be deposited in the desired mask pattern or patterned after deposition.

### CROSS-REFERENCE TO RELATED APPLICATIONS

This application is a continuation of PCT Application PCT/US2022/049438 filed Nov. 9, 2022, which claims benefit of priority to U.S. Provisional Patent Application No. 63/286,237 filed Dec. 6, 2021. Both of the above applications are incorporated herein by reference in its entirety.

### FIELD OF THE INVENTION

The invention relates generally to pcLEDs, pcLED arrays, light sources comprising pcLEDs or pcLED arrays, and displays comprising pcLED arrays.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Technological and business applications of pcLEDs include use in displays, matrices and light engines including automotive adaptive headlights, augmented-reality (AR) displays, virtual-reality (VR) displays, mixed-reality (MR) displays, smart glasses and displays for mobile phones, smart watches, monitors and TVs, and flash illumination for cameras in mobile phones. The individual LED pixels in these architectures can have an area of a few square millimeters down to a few square micrometers depending on the matrix or display size and its pixel per inch requirements. LED matrices/displays may for example be realized by transfer and attachment of individual pixels from a donor substrate to a controller backplane or electronic board or be created by a monolithic approach where a monolithically integrated array of LED pixels is processed into an LED module on a donor epitaxial wafer and then transferred and attached to a controller backplane.

### SUMMARY

The invention relates to a method for depositing patterned phosphor films by using a patterned polymer (e.g., latex) film as a mask to block phosphor deposition, or allow subsequent removal of deposited phosphor, from selected masked areas of a device surface. This offers an easy and efficient method that is applicable for a wide range of applications. The phosphor films may be deposited by sedimentation or electrophoretic deposition (EPD) of phosphor grains (particles), for example, and may be advantageously thin and highly uniform.

The patterned polymer film mask may be configured for example to cover areas around the periphery of a single LED or around the periphery of an array of LEDs (e.g., a microLED array), for example protecting contact areas for circuitry located in those peripheral areas to serve the LED or array of LEDs. Alternatively, or in addition, the mask may cover lanes between LEDs in an array to prevent phosphor deposition in or over those lanes, to reduce cross-talk (light leakage) between adjacent pcLED pixels in an array.

The method generally comprises disposing the patterned polymer film mask on the device, subsequently depositing the phosphor particles, and then removing the mask and any phosphor particles deposited on the mask from the device. The polymer film may be deposited in the desired mask pattern or patterned after deposition.

In some variations, before removing the mask a dielectric coating is applied to the phosphor particles to bind them to each other and to the underlying device. The dielectric coating may be applied by chemical vapor deposition or atomic layer deposition, for example. In such variations the polymer film may protect the portions of the device covered by the mask from the dielectric material coating, which is removed from the portions of the device covered by the mask along with the mask.

The patterned phosphor deposition methods disclosed herein may be advantageously employed in manufacturing pcLEDs and arrays of pcLEDs (e.g., microLED arrays) used for example in the various devices and applications listed above in the Background section.

These and other embodiments, features and advantages of the present invention will become more apparent to those skilled in the art when taken with reference to the following more detailed description of the invention in conjunction with the accompanying drawings that are first briefly described

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system comprising an adaptive illumination system.

FIG. 6 schematically illustrates an example display (e.g., AR/VR/MR) system that includes an adaptive illumination system.

FIG. 7A shows a schematic cross-sectional view of an example light emitting device disposed on a substrate.

FIG. 7B shows a schematic cross-sectional view, and FIG. 7C shows a corresponding schematic top view, of a patterned polymer film disposed on the surface of the substrate shown in FIG. 7A, around the periphery of the light emitting device but not on the top light emitting surface of the light emitting device.

FIG. 7D shows a schematic cross-sectional view of a layer of phosphor particles disposed on the light emitting device and on the patterned polymer film of FIGS. 7B-7C.

FIG. 7E shows a schematic cross-sectional view in which an optional dielectric coating layer has been disposed on the phosphor particles of FIG. 7D.

FIG. 7F shows a schematic cross-sectional view in which the optional dielectric coating of FIG. 7E is disposed on a polymer film without being disposed around the polymer film.

FIG. 8 shows a schematic top view of an array of LEDs disposed on a substrate, with a patterned polymer film disposed on the surface of substrate around the periphery of the array of LEDs and also around the periphery of each individual LED over the lanes between the LEDs, but not on top light emitting surfaces of the LEDs.

FIG. 9A shows a schematic top view of an array of LEDs disposed on a substrate, with a patterned polymer film mask disposed on the surface of the substrate around the periphery of the array, around the periphery of each individual LED in a first row of LEDs in the array, and on top light emitting surfaces of LEDs in second and third rows of LEDs in the array, but not on top light emitting surfaces of the LEDs in the first row of LEDs in the array.

FIG. 9B shows a schematic top view of an array of LEDs disposed on a substrate, with a patterned polymer film mask disposed on the surface of the substrate around the periphery of the array, around the periphery of each individual LED in a second row of LEDs in the array, and on top light emitting surfaces of LEDs in first and third rows of LEDs in the array, but not on top light emitting surfaces of the LEDs in the second row of LEDs in the array.

FIG. 9C shows a schematic top view of an array of LEDs disposed on a substrate, with a patterned polymer film mask disposed on the surface of the substrate around the periphery of the array, around the periphery of each individual LED in a third row of LEDs in the array, and on top surfaces of LEDs in first and second rows of LEDs in the array, but not on top light emitting surfaces of the LEDs in the third row of LEDs in the array.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

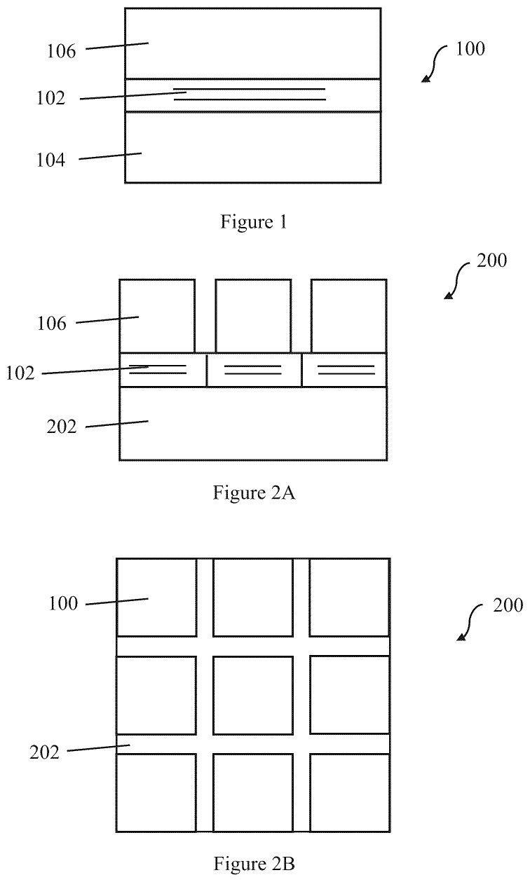

FIG. 1 shows an example of an individual pcLED 100 comprising a light emitting semiconductor diode (LED) structure 102 disposed on a substrate 104, and a phosphor layer 106 (also referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED.

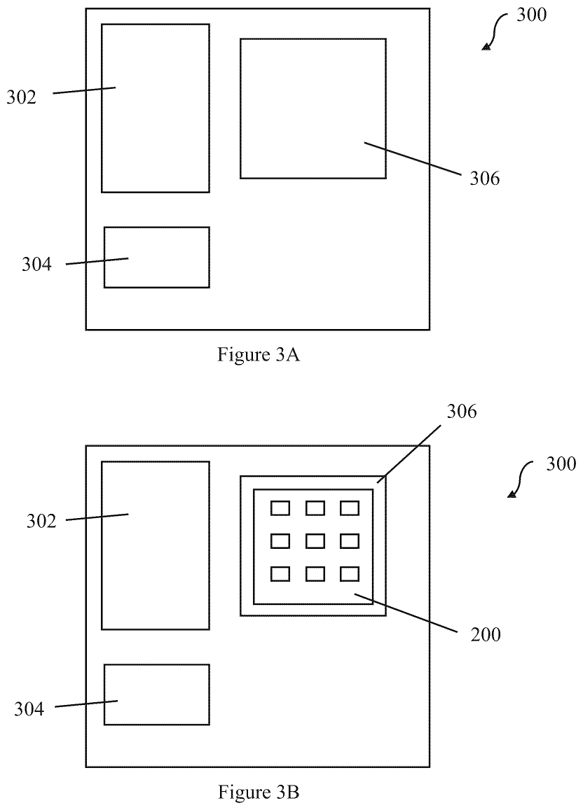

FIGS. 2A-2B show, respectively, cross-sectional and top views of an array 200 of pcLEDs 100 including phosphor pixels 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from separate individual pcLEDs. Substrate 202 may optionally comprise CMOS circuitry for driving the LED and may be formed from any suitable materials.

Although FIGS. 2A-2B show a three-by-three array of nine pcLEDs, such arrays may include for example tens, hundreds, or thousands of LEDs. Individual LEDs (pixels) may have widths (e.g., side lengths) in the plane of the array, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular pixels arranged in a symmetric matrix, the pixels and the array may have any suitable shape or arrangement.

LEDs having dimensions in the plane of the array (e.g., side lengths) of less than or equal to about 50 microns are typically referred to as microLEDs, and an array of such microLEDs may be referred to as a microLED array.

An array of LEDs, or portions of such an array, may be formed as a segmented monolithic structure in which individual LED pixels are electrically isolated from each other by trenches and/or insulating material, but the electrically isolated segments remain physically connected to each other by portions of the semiconductor structure.

The individual LEDs in an LED array may be individually addressable, may be addressable as part of a group or subset of the pixels in the array, or may not be addressable. Thus, light emitting pixel arrays are useful for any application requiring or benefiting from fine-grained intensity, spatial, and temporal control of light distribution. These applications may include, but are not limited to, precise special patterning of emitted light from pixel blocks or individual pixels. Depending on the application, emitted light may be spectrally distinct, adaptive over time, and/or environmentally responsive. Such light emitting pixel arrays may provide pre-programmed light distribution in various intensity, spatial, or temporal patterns. The emitted light may be based at least in part on received sensor data and may be used for optical wireless communications. Associated electronics and optics may be distinct at a pixel, pixel block, or device level.

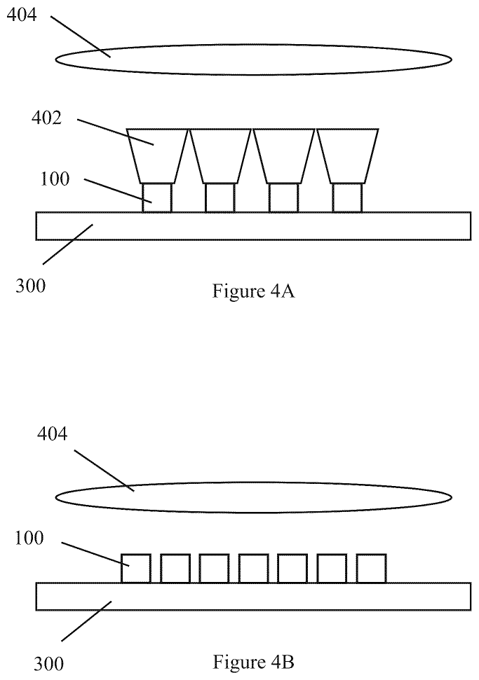

As shown in FIGS. 3A-3B, a pcLED array 200 may be mounted on an electronics board 300 comprising a power and control module 302, a sensor module 304, and an LED attach region 306. Power and control module 302 may receive power and control signals from external sources and signals from sensor module 304, based on which power and control module 302 controls operation of the LEDs. Sensor module 304 may receive signals from any suitable sensors, for example from temperature or light sensors. Alternatively, pcLED array 200 may be mounted on a separate board (not shown) from the power and control module and the sensor module.

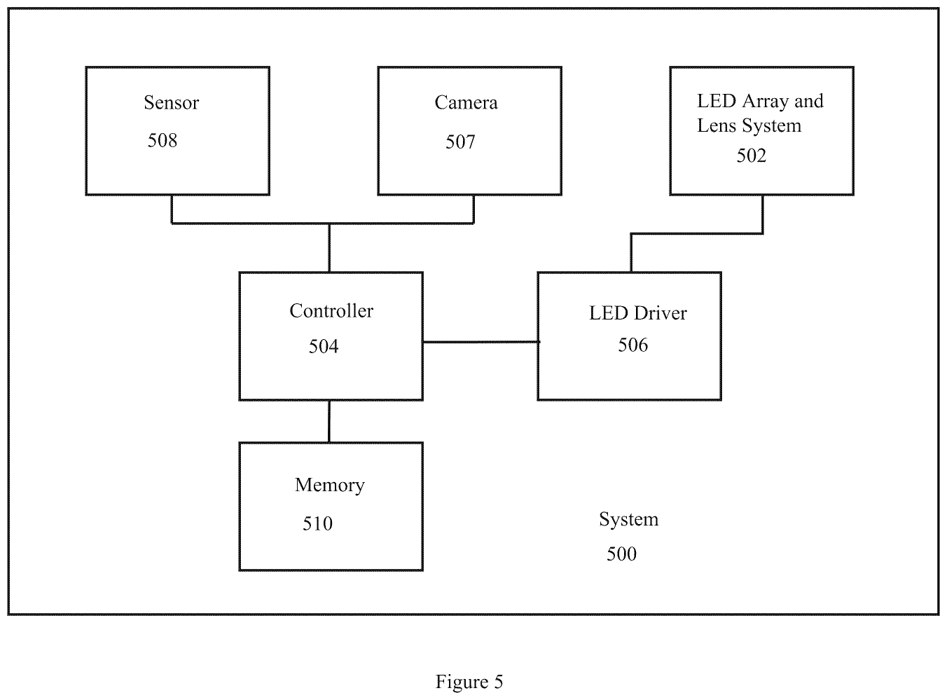

Individual pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B a pcLED array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when pcLEDs can be spaced sufficiently close to each other and may also be used in automobile headlights as well as in camera flash applications. A microLED display application may use similar optical arrangements to those depicted in FIGS. 4A-4B, for example. Generally, any suitable arrangement of optical elements may be used in combination with the LED arrays described herein, depending on the desired application.

An array of independently operable LEDs may be used in combination with a lens, lens system, or other optical system (e.g., as described above) to provide illumination that is adaptable for a particular purpose. For example, in operation such an adaptive lighting system may provide illumination that varies by color and/or intensity across an illuminated scene or object and/or is aimed in a desired direction. A controller can be configured to receive data indicating locations and color characteristics of objects or persons in a scene and based on that information control LEDs in an LED array to provide illumination adapted to the scene. Such data can be provided for example by an image sensor, or optical (e.g., laser scanning) or non-optical (e.g., millimeter radar) sensors. Such adaptive illumination is increasingly important for automotive, mobile device camera, VR, and AR applications.

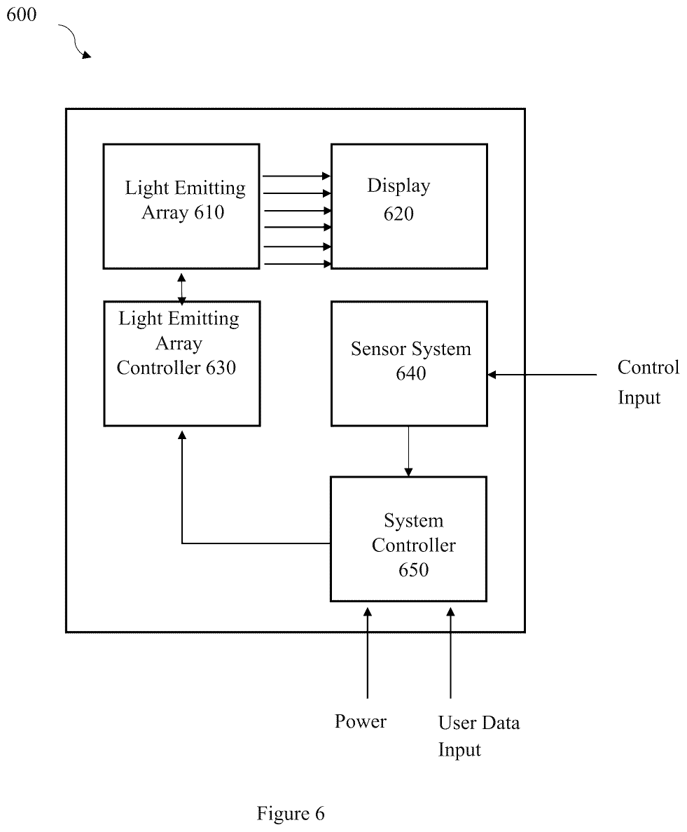

FIG. 5 schematically illustrates an example camera flash system 500 comprising an LED array and lens system 502, which may be similar or identical to the systems described above. Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and adaptive illumination system 502 may be controlled by controller 504 to match their fields of view.

Sensors 508 may include, for example, positional sensors (e.g., a gyroscope and/or accelerometer) and/or other sensors that may be used to determine the position, speed, and orientation of system 500. The signals from the sensors 508 may be supplied to the controller 504 to be used to determine the appropriate course of action of the controller 504 (e.g., which LEDs are currently illuminating a target and which LEDs will be illuminating the target a predetermined amount of time later).

In operation, illumination from some or all pixels of the LED array in 502 may be adjusted—deactivated, operated at full intensity, or operated at an intermediate intensity. Beam focus or steering of light emitted by the LED array in 502 can be performed electronically by activating one or more subsets of the pixels, to permit dynamic adjustment of the beam shape without moving optics or changing the focus of the lens in the lighting apparatus.

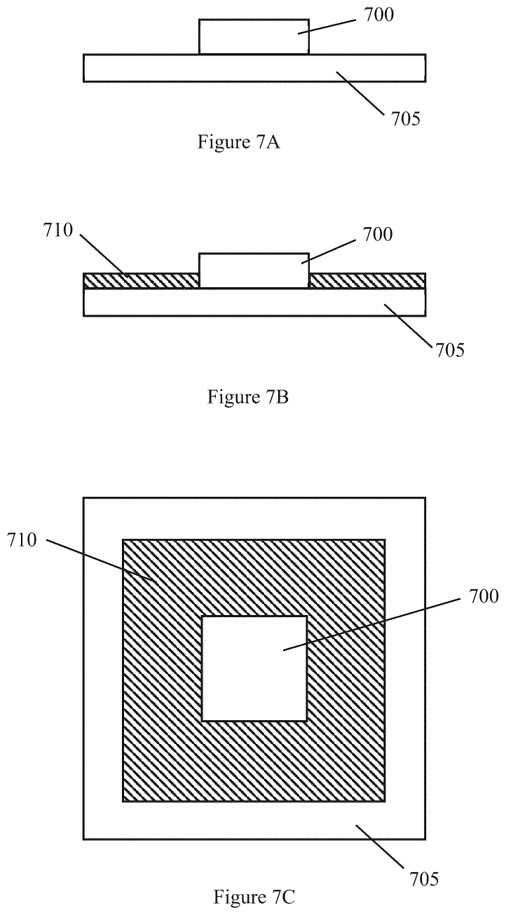

FIG. 6 schematically illustrates an example display (e.g., AR/VR/MR) system 600 that includes an adaptive light emitting array 610, display 620, a light emitting array controller 630, sensor system 640, and system controller 650. Control input is provided to the sensor system 640, while power and user data input is provided to the system controller 650. In some embodiments modules included in system 600 can be compactly arranged in a single structure, or one or more elements can be separately mounted and connected via wireless or wired communication. For example, the light emitting array 610, display 620, and sensor system 640 can be mounted on a headset or glasses, with the light emitting controller and/or system controller 650 separately mounted.

The light emitting array 610 may include one or more adaptive light emitting arrays, as described above, for example, that can be used to project light in graphical or object patterns that can support AR/VR/MR systems. In some embodiments, arrays of microLEDs can be used.

System 600 can incorporate a wide range of optics in adaptive light emitting array 610 and/or display 620, for example to couple light emitted by adaptive light emitting array 610 into display 620.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, eye or pupil positioning, or connected keyboard, mouse, or game controller.

As summarized above, this specification discloses methods for depositing patterned phosphor films by using a patterned polymer film as a patterned mask to block phosphor deposition, or allow subsequent removal of deposited phosphor, from selected areas of a device surface.

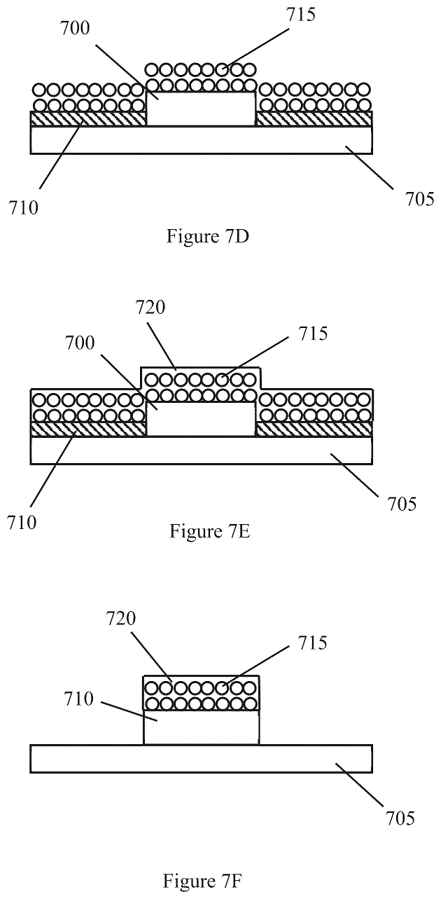

FIG. 7A shows a schematic cross-sectional view of an example light emitting device 700 disposed on a substrate 705. Light emitting device 700 may be, for example, a single semiconductor LED or an array of two or more semiconductor LEDs. In instances where light emitting device 700 is an array of LEDs, it may be a monolithic array or an array of discrete LEDs. The LEDs may have any suitable dimensions and may for example be microLEDs.

FIG. 7B shows a schematic cross-sectional view, and FIG. 7C shows a corresponding schematic top view, of a polymer film 710 patterned to cover the surface of substrate 705 around the periphery of light emitting device 700 but not the top light emitting surface of the light emitting device. The patterned polymer film may overly and thus protect electrical contacts for driving circuitry, or other components, located on or in substrate 705 around the periphery of light emitting device 700.

The polymer film may be directly deposited in the desired mask pattern (e.g., around the periphery of light emitting device 700 but not on light emitting device 700). Alternatively, the polymer coating may be initially deposited as a uniform coating, for example covering light emitting device 700 as well as peripheral areas of substrate 700, and then patterned to form the desired mask pattern.

FIG. 7D shows a schematic cross-sectional view of a layer of phosphor particles 715 disposed on the light emitting device 700 and patterned polymer film 710 of FIGS. 7B-7C. Phosphor particles 715 may be deposited by sedimentation or by electrophoretic deposition, for example.

Optionally, as shown schematically in cross-section in FIG. 7E, after phosphor particles 715 are deposited a dielectric coating 720 may be deposited by chemical vapor deposition or atomic layer deposition methods, for example, to coat and bind phosphor particles 715 to each other and to light emitting device 700.

After deposition of the phosphor particles and the optional coating step, patterned polymer film 710 may be removed along with any phosphor particles and/or coating material disposed on it. FIG. 7F shows a schematic cross-sectional view of the resulting light emitting device 700 disposed on substrate 705, with phosphor particles 715 disposed on a top light-emitting surface of light emitting device 700 but not on peripheral portions of substrate 705.

In instances in which light emitting device 700 is an array of LEDs, the method illustrated in FIGS. 7A-7F results in a layer of phosphor particles disposed uniformly across the array, over the LEDs and also over the lanes between the LEDs in the array.

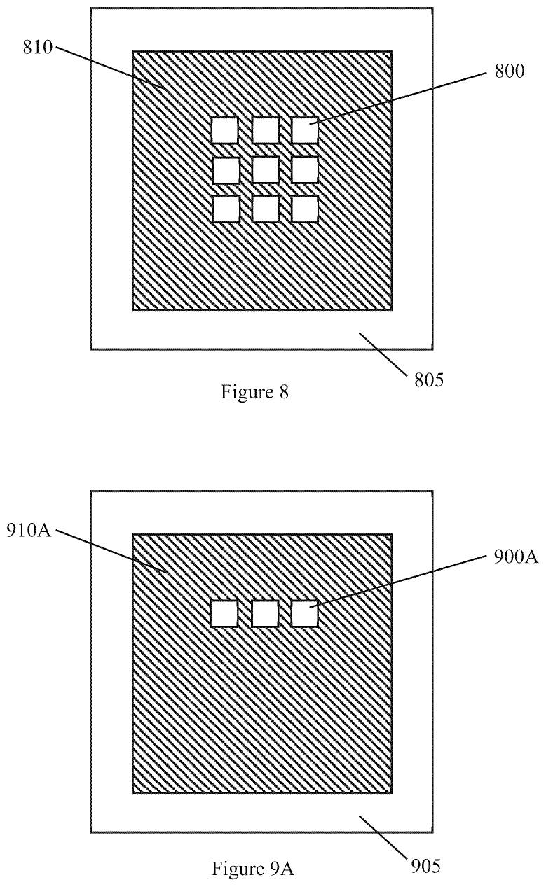

FIG. 8 shows a schematic top view of an array of LEDs 800 disposed on a substrate 805, with a polymer film 810 patterned to cover the surface of substrate 805 around the periphery of the array of LEDs, and also around the periphery of each individual LED, over the lanes between the LEDs. Further phosphor deposition, optional coating, and mask removal steps as described above with respect to FIGS. 7A-7F will result in an array with phosphor particles 715 disposed on top light-emitting surfaces of the LEDs 800 but not in or over the lanes between LEDs or around the periphery of the array.

The method illustrated by FIG. 8 results in an array in which the same type (e.g., color) of phosphor is deposited on each LED.

In a further variation, different types of phosphor (e.g., red, green, and blue) may be deposited on different ones of the LEDs in an array using a sequence of similar masking steps.

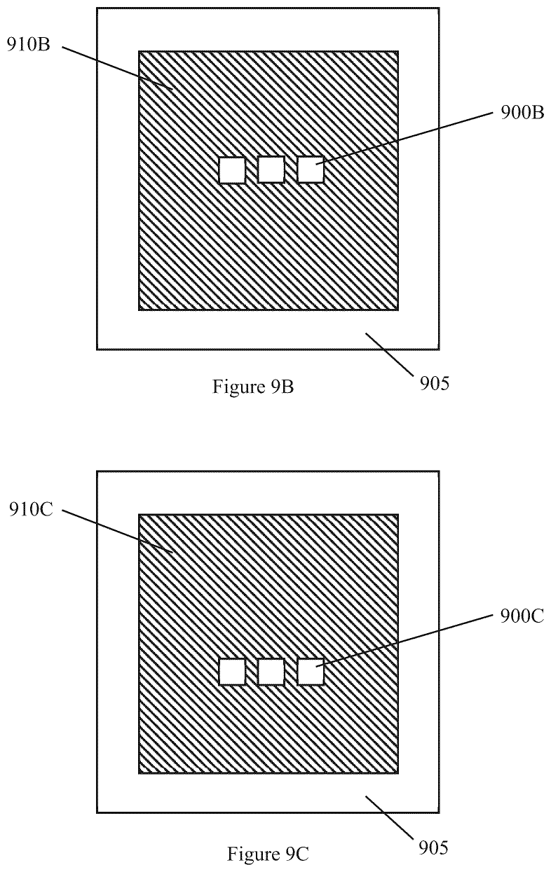

As an example, FIG. 9A shows a schematic top view of an array of LEDs disposed on a substrate 905, with a polymer film mask 910A patterned to cover the surface of substrate 905 around the periphery of the array, around the periphery of each individual LED 900A in a first row of LEDs in the array, and to cover top surfaces of LEDs 900B (FIG. 9B) and 900C (FIG. 9C) in second and third rows of LEDs in the array. A phosphor of a first type (e.g., color) may be deposited on LEDs 900A.

After mask 910A is removed along with any phosphor and optional coating material disposed on it, as shown in the schematic top view of FIG. 9B a second patterned polymer film mask 910B is disposed on the surface of substrate 905 around the periphery of the array, around the periphery of each individual LED 900B in a second row of LEDs in the array, and on top surfaces of LEDs 900A and LEDs 900C. A phosphor of a second type may be deposited on LEDs 900B. Patterned polymer film mask 910B is then removed along with any phosphor and optional coating material disposed on it.

In this manner phosphors of different colors may be deposited on different ones of the LEDs in the array, without depositing phosphor on or in the lanes between the LEDs.

If the individual LEDs emit blue light, and the two phosphor types are red and green, then if no phosphor is deposited on LEDs 900C the array will comprise direct emitting blue LEDs, red emitting pcLEDs, and green emitting pcLEDs. Any other suitable combination of pcLEDs of different colors and direct emitting (e.g., blue) LEDs may be created in this manner.

Alternatively, as shown in the schematic top view of FIG. 9C a third patterned polymer film mask 910C may be disposed on the surface of substrate 905 around the periphery of the array, around the periphery of each individual LED 900C in a third row of LEDs in the array, and on top surfaces of LEDs 900A and LEDs 900B. A phosphor of a third type may be deposited on LEDs 900C. Patterned polymer film mask 910C is then removed along with any phosphor and optional coating material disposed on it.

This scheme may be extended to any desired number of phosphor types by use of a continuing sequence of suitable mask patterns.

Further, although for simplicity of discussion FIGS. 9A-9C illustrate use of patterned polymer film masks that leave a row of LEDs uncovered and mask the remaining LEDs, the uncovered LEDs may instead extend along a diagonal a rectangular array, or occupy alternating locations in the array (e.g., in a checkerboard pattern), or occur in any other desired pattern in the array.

The arrays shown in FIG. 8 and FIGS. 9A-9C may be microLED arrays, for example, in which the LEDs have side lengths of about 50 microns or less, and the spacing between adjacent LEDs (lane width) is less than 20 microns, or less than 10 microns, or less than 5 microns. Alternatively, the LEDs in the array may be larger in size, and optionally spaced by larger distances. The arrays may have an active area of, for example, about 5 mm by about 12 mm, though arrays of any other suitable dimensions may be used.

In the methods described above, the polymer film mask may be formed from a latex dispersion that is applied to the device and then cured to form an elastic polymer layer having a thickness of, for example, about 1 micron to about 200 microns thick, or about 1 micron to about 150 microns thick, or about 1 micron to about 100 microns thick, or about 2 microns thick, or about 5 microns thick.

As used herein, the term latex dispersion refers to a stable dispersion (emulsion) of polymer microparticles in a solvent.

The liquid solvent can include any one or more liquids suitable for dispersing the polymer particles and for enabling drying (e.g., solvent evaporation) and curing (e.g., by further polymerization or cross-linking) of the latex dispersion to form the cured polymer layer. In some examples, the liquid solvent of the latex dispersion can include water; in some examples the resulting aqueous latex dispersion can be a natural or synthetic latex. In some examples the liquid solvent can include one or more nonaqueous solvents (polar or nonpolar); in some of those examples the liquid solvent can also exclude water. In some examples, the latex dispersion and the cured polymer layer can include polyisoprene (i.e., polymerized 2 methyl-1,3 butadiene, also known as cis-1,4 polyisoprene). Other suitable polymers can be employed.

In some examples, the latex dispersion can include one or more cross-linking agents. In some examples, the latex dispersion can include one or more heat-resistant compounds. In some examples, the cured polymer layer can withstand a temperature greater than about 100° C., greater than about 150° C., greater than about 200° C., or greater than about 250° C. In some examples, the latex dispersion can include one or more chemical-resistant compounds. In some examples the cured polymer layer can be chemically resistant to one or more cleaning chemicals, one or more ALD reagents, one or more CVD reagents, or one or more dry or wet etchants.

The latex dispersion may for example comprise particles of natural rubber or similar polymers in water with alkaline additives that cross-link during curing (e.g., drying) of the dispersion to form an easily removable (e.g., peelable) coating.

A layer of the latex dispersion may be formed on the device in the desired mask pattern by spatially selective dispensing, ink-jet printing, screen printing, slot-die coating, or any other suitable method before being dried and cured to form the desired cured patterned polymer film mask.

Alternatively, an unpatterned layer of the latex dispersion can be formed initially (e.g., by dispensing, spin coating, slot-die coating, or doctor-blade coating), then dried and cured. After drying and curing, portions of the cured polymer layer can be removed to form the desired patterned polymer film mask. Such patterning may be accomplished, for example, using mechanical (e.g., peeling, scraping, or abrading) techniques, a plasma process, or by laser patterning (e.g., laser ablation).

The phosphor particles may be deposited by, for example, sedimentation or electrophoretic deposition. In the sedimentation process the device is placed under a liquid, and a phosphor suspension is added above the device. The phosphor particles descend slowly through the liquid and accumulate to form a uniform layer on the device. In the electrophoretic deposition process the device is electrically contacted to a cathode. The device and the cathode, together with an anode, are placed in a suspension containing phosphor particles, stabilized with positively charged surfactants. When a voltage is applied between the anode and the cathode the phosphor particles travel along electrical field lines to the device, where they accumulate to form a uniform layer. In either process, after deposition the phosphor particle layer is dried to fix the particles in place.

The phosphor particles may have a D50 (i.e., median transverse dimension) diameter of, for example, about 1 micron to about 5 microns, about 3 microns to about 4 microns, or any other suitable diameter. The layers of phosphor particles (including any optional dielectric coating layer applied to bind them to each other and to the device) may have thickness of about 10 microns to about 20 microns, or about 15 microns to about 20 microns, or any other suitable thickness.

The phosphor particles may be particles of YAG doped with a Rare Earth element, for example. Any other suitable phosphor particles may also be used.

In variations in which a dielectric coating layer is deposited on the phosphor particles, typically atomic layer deposition (ALD) or another suitable chemical vapor deposition (CVD) process is employed for depositing the coating layer material. A typical ALD reaction is split into (at least) two parts, one involving an oxide precursor (e.g., metal or semiconductor halides, amides, alkyl amides, or alkoxides, or other metal, semiconductor, or organometallic compounds) and the other involving an oxygen source (e.g., water, ozone, or other suitable oxygen source). Alternating those steps and purging the reactor after each step lead to formation of atomic layers (or monolayers) due to the self-limiting nature of the surface reaction. The ALD sequence can be tailored in any suitable way to yield a coating layer having desired composition, spatial properties, or optical properties. In some examples the coating layer can be formed at temperatures less than about 150° C. (e.g., if some or all of the electronic components on the substrate 202 cannot tolerate excessive heating).

The optional dielectric coating may be or comprise, for example, one or more metal or semiconductor oxides, such as Al₂O₃, HfO₂, SiO₂, Ga₂O₃, GeO₂, SnO₂, CrO₂, TiO₂, Ta₂O₅, Nb₂O₅, V₂O₅, Y₂O₃, or ZrO₂.

In one variation the phosphor particles are particles of YAG doped with a Rare Earth element, coated with a thin Al₂O₃ film.

After deposition, drying, and optional coating of the phosphor particles, the patterned polymer film mask is removed along with any phosphor particles, coating material, or other material dispose on the mask. In some variations, the polymer film mask is easily removed mechanically, by peeling for example, due to its high elasticity. Alternatively, the polymer film mask may be removed by dissolving it in an (e.g., organic) solvent, or by any other suitable process.

This disclosure is illustrative and not limiting. Further modifications will be apparent to one skilled in the art in light of this disclosure and are intended to fall within the scope of the appended claims.

What is claimed is:

1. A method of depositing a phosphor layer on a light emitting device disposed on a top surface of a substrate, the method comprising:
disposing a polymer film on areas of the top surface of the substrate around the periphery of the light emitting device, the polymer film not covering a top light emitting surface of the light emitting device;
depositing phosphor particles on the polymer film and on the top surface of the light emitting device; and
removing the polymer film, and any phosphor particles disposed on it, from the top surface of the substrate without removing phosphor particles disposed on the top surface of the light emitting device.

2. The method of claim 1, wherein the light emitting device comprises a microLED array.

3. The method of claim 1, comprising:
depositing a stable dispersion of polymer particles in a solvent on the areas of the top surface of the substrate around the periphery of the light emitting device and not on the top light emitting surface of the light emitting device; and
curing the dispersion of polymer particles to form the polymer film disposed on the areas of the top surface of the substrate around the periphery of the light emitting device.

4. The method of claim 1, comprising:
depositing a stable dispersion of polymer particles in a solvent on the areas of the top surface of the substrate around the periphery of the light emitting device and on the top light emitting surface of the light emitting device;
removing the portion of the stable dispersion deposited on the top surface of the light emitting device; and
curing the remaining portion of the dispersion of polymer particles to form the polymer film disposed on the areas of the top surface of the substrate around the periphery of the light emitting device.

5. The method of claim 1, comprising:
depositing a stable dispersion of polymer particles in a solvent on the areas of the top surface of the substrate around the periphery of the light emitting device and on the top light emitting surface of the light emitting device;
curing the dispersion of polymer particles to form a polymer film disposed on the areas of the top surface of the substrate around the periphery of the light emitting device and on the top light emitting surface of the light emitting device; and
removing the polymer film from the top light emitting surface of the light emitting device without removing the polymer film disposed on the top surface of the substrate around the periphery of the light emitting device.

6. The method of claim 5, wherein the polymer particles are particles of natural rubber and the solvent is water.

7. The method of claim 6, wherein the stable dispersion comprises alkaline cross-linking agents.

8. The method of claim 1, comprising depositing a dielectric coating on the phosphor particles after depositing the phosphor particles on the polymer film and before removing the polymer film from the top surface of the substrate, the dielectric coating binding the phosphor particles to each other.

9. The method of claim 8, comprising depositing the dielectric coating using an atomic layer deposition process.

10. A method of depositing a phosphor layer on a light emitting device disposed on a top surface of a substrate, the light emitting device comprising an array of LEDs spaced apart from each other by lanes, the method comprising:
disposing a polymer film on areas of the top surface of the substrate around the periphery of the light emitting device and over the lanes in the array of LEDs, the polymer film not covering top light emitting surfaces of the LEDs;
depositing phosphor particles on the polymer film and on the top light emitting surfaces of the LEDs; and
removing the polymer film, and any phosphor particles disposed on it, from the top surface of the substrate and from over the lanes in the array of LEDs without removing phosphor particles disposed on the top light emitting surfaces of the LEDs.

11. The method of claim 10, wherein the array of LEDs is a microLED array.

12. The method of claim 10, comprising:
depositing a stable dispersion of polymer particles in a solvent on the areas of the top surface of the substrate around the periphery of the light emitting device and over the lanes in LED array, and not on the top light emitting surfaces of the LEDs; and
curing the dispersion of polymer particles to form the polymer film disposed on the areas of the top surface of the substrate around the periphery of the light emitting device and over the lanes in the array of LEDs.

13. The method of claim 10, comprising:
depositing a stable dispersion of polymer particles in a solvent on the areas of the top surface of the substrate around the periphery of the light emitting device, on the top light emitting surfaces of the LEDs, and over the lanes in the LED;
removing the portion of the stable dispersion deposited on the top light emitting surfaces of the LEDs; and
curing the remaining portion of the dispersion of polymer particles to form the polymer film disposed on the areas of the top surface of the substrate around the periphery of the light emitting device and over the lanes in the array of LEDs.

14. The method of claim 10, comprising:
depositing a stable dispersion of polymer particles in a solvent on the areas of the top surface of the substrate around the periphery of the light emitting device, on the top light emitting surfaces of the LEDs, and over the lanes in the LED;
curing the dispersion of polymer particles to form a polymer film disposed on the areas of the top surface of the substrate around the periphery of the light emitting device, on the top light emitting surfaces of the LEDs, and over the lanes in the LED; and
removing the polymer film from the top light emitting surfaces of the LEDs without removing the polymer film disposed on the top surface of the substrate around the periphery of the light emitting device and over the lanes in the array of LEDs.

15. A method of depositing phosphors of different types on a light emitting device disposed on a top surface of a substrate, the light emitting device comprising an array of LEDs spaced apart from each other by lanes, the method comprising:
disposing a first polymer film on areas of the top surface of the substrate around the periphery of the light emitting device, over the lanes in the array of LEDs, and on top light emitting surfaces of a first group of the LEDs, the polymer film not covering top light emitting surfaces of a second group of the LEDs;
depositing phosphor particles of a first type on the first polymer film and on the top light emitting surfaces of the second group of LEDs;
removing the first polymer film, and any phosphor particles of the first type disposed on it, from the top surface of the substrate, from over the lanes in the array of LEDs, and from the top light emitting surfaces of the first group of the LEDs without removing phosphor particles of the first type disposed on the top light emitting surfaces of the second group of the LEDs;
disposing a second polymer film on areas of the top surface of the substrate around the periphery of the light emitting device, over the lanes in the array of LEDs, and over top light emitting surfaces of the second group of the LEDs, the polymer film not covering top light emitting surfaces of the first group of the LEDs;
depositing phosphor particles of a second type on the second polymer film and on the top light emitting surfaces of the first group of LEDs; and
removing the second polymer film, and any phosphor particles of the second type disposed on it, from the top surface of the substrate and from over the lanes in the array of LEDs without removing phosphor particles of the second type disposed on the top light emitting surfaces of the first group of LEDs.

16. The method of claim 15, wherein the array of LEDs is a microLED array.

17. The method of claim 15, wherein one of the first type and the second type of phosphors is a green phosphor type and the other of the first type and the second type of phosphors is a red phosphor type.

18. The method of any of claim 15, wherein the first polymer film and the second polymer film are formed from stable dispersions of polymer particles in a solvent.

19. The method of claim 18, wherein the polymer particles are particles of natural rubber and the solvent is water.

20. The method of claim 19, wherein the stable dispersion comprises alkaline cross-linking agents.
